(19) United States
(12) Patent Application Publication
(10) Pub. No.: US 2011/0233407 A1
(43) Pub. Date: Sep. 29, 2011

(54) ELECTRONIC DEVICE WITH LOCK FUNCTION AND METHOD FOR LOCKING ELECTRONIC DEVICE

(75) Inventors: WEI WU, Shenzhen City (CN); XIN YANG, Shenzhen City (CN)

(73) Assignees: FU TAI HUA INDUSTRY (SHENZHEN) CO., LTD., ShenZhen City (CN); HON HAI PRECISION INDUSTRY CO., LTD., Tu-Cheng (TW)

(21) Appl. No.: 12/846,851

(22) Filed: Jul. 30, 2010

(30) Foreign Application Priority Data
Mar. 25, 2010 (CN) 201010132362.8

(51) Int. Cl. G01P 13/02; H01L 31/09; G01S 15/88

(52) U.S. Cl. 250/338.1; 250/340; 250/206.1; 250/208.4; 367/93

(57) ABSTRACT

An electronic device includes a processing unit, a first sensor, and a second sensor. The first and the second sensors are configured to generate signals if an object is within their detection zone. The processing unit is configured to receive the signals from the first sensor and the second sensor, and determine whether to lock or unlock the electronic device according to a sequence of the signals it receives from the first sensor and the second sensor within a predetermined time period.

### BACKGROUND

1. Technical Field

The present disclosure relates to electronic devices and methods thereof, particularly, to an electronic device having a lock and unlock function and a method for locking and unlocking the electronic device.

2. Description of Related Art

Nowadays, electronic devices such as mobile phones are very popular. Usually, to forbid unauthorized use of the electronic device, the owner of the electronic device can set a password for the electronic device to lock the electronic device, therefore, if a person does not input the correct password, the electronic device is unable to verify the input password to unlock the device, namely, the electronic device stays locked.

However, the usual method to set the password or input the password is to use the keyboard to input numbers or letters, if the user wants to lock or unlock the device, the user usually should press one or more keys, which is inconvenient.

### BRIEF DESCRIPTION OF THE DRAWINGS

The components in the drawings are not necessarily drawn to scale, the emphasis instead being placed upon clearly illustrating the principles of the electronic device. Moreover, in the drawings, like reference numerals designate corresponding parts throughout the several views.

FIG. 1 is a block diagram of an electronic device in accordance with an exemplary embodiment.

FIG. 2 is a schematic view showing how to lock or unlock the electronic device of FIG. 1.

FIG. 3 is a flowchart illustrating a method for locking or unlocking the electronic device of FIG. 1, in accordance with an exemplary embodiment.

### DETAILED DESCRIPTION

Embodiments of the present disclosure will now be described in detail below, with reference to the accompanying drawings.

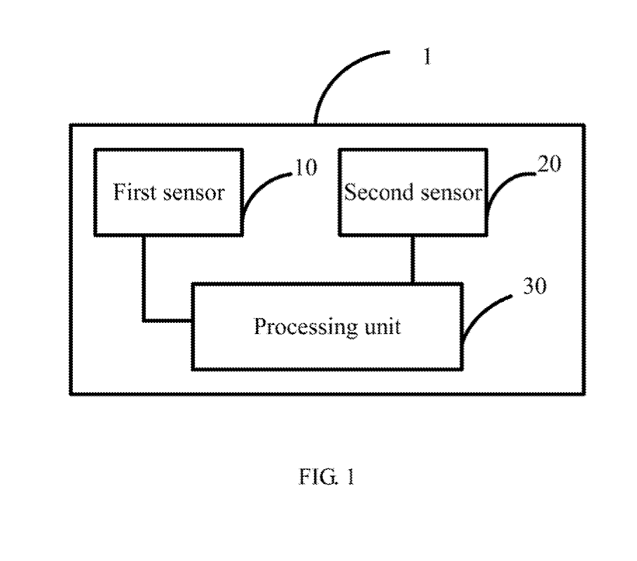

Referring to FIG. 1, an electronic device 1 includes a first sensor 10, a second sensor 20, and a processing unit 30. The first sensor 10 and the second sensor 20 are configured to detect whether an object is in their detection zone, and are configured to sense and generate signals if an object is in their detection zone. The processing unit 30 is connected to both the first sensor 10 and the second sensor 20, and is configured to selectively lock or unlock the electronic device 1 according to the signal sequence it receives from the two sensors 10 and 20.

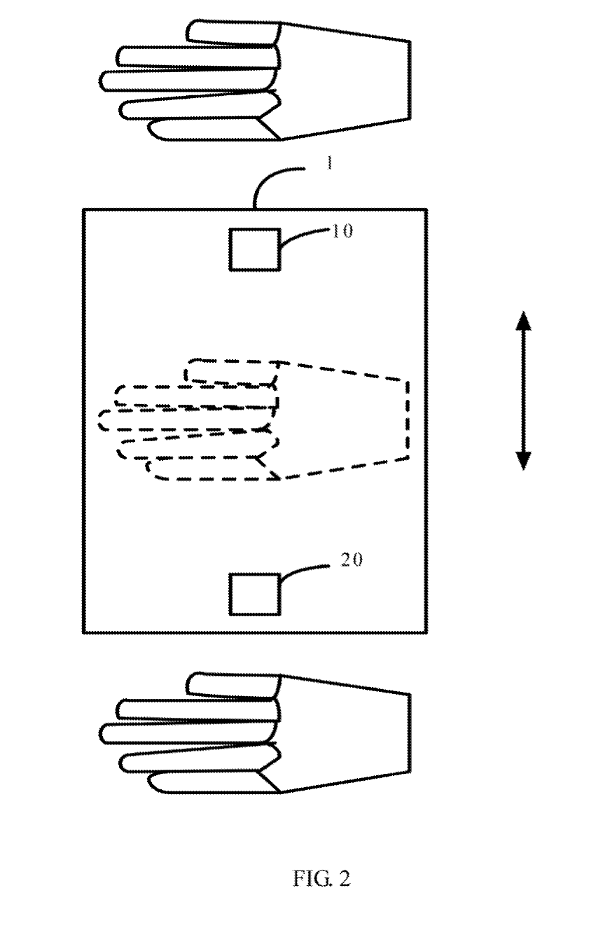

Referring also to FIG. 2, in this embodiment, the first sensor 10 and the second sensor 20 are respectively located at an upper end and a lower end of the electronic device 1. In an alternative embodiment, the first sensor 10 and the second sensor 20 can be located at any suitable positions of the electronic device 1. The first sensor 10 and the second sensor 20 can be light sensors, infrared sensors, or ultrasonic wave sensors. The first sensor 10 and the second sensor 20 can be the same type sensors or different type sensors.

If the first sensor 10 or the second sensor 20 detects that an object, such as a palm of a user, is within it's detection zone, the first sensor 10 or the second sensor 20 generates a signal. When the processing unit 30 receives the signal from either one of the sensors 10 or 20, the processing unit 30 detects whether a signal from the other sensor is received within a predetermined time period (e.g., 2 seconds). If the processing unit 30 receives the sensed signal from the other sensor within the predetermined time period, the processing unit 30 determines the movement direction of the object according to the sequence of the signals.

In this embodiment, if the processing unit 30 determines that the movement direction of the object is a first direction, the processing unit 30 locks the electronic device 1. If the processing unit 30 determines that the movement direction of the object is a second direction, the processing unit 30 unlocks the electronic device 1. In this embodiment, the first direction is from the first sensor 10 to the second sensor 20, and the second direction is from the second sensor 20 to the first sensor 10. In other embodiments, any combination of first and second directions can be used to lock or unlock the electronic device 1. As an alternative example, the first direction can also be from the second sensor 20 to the first sensor 10, and the second direction is from the first sensor 10 to the second sensor 20.

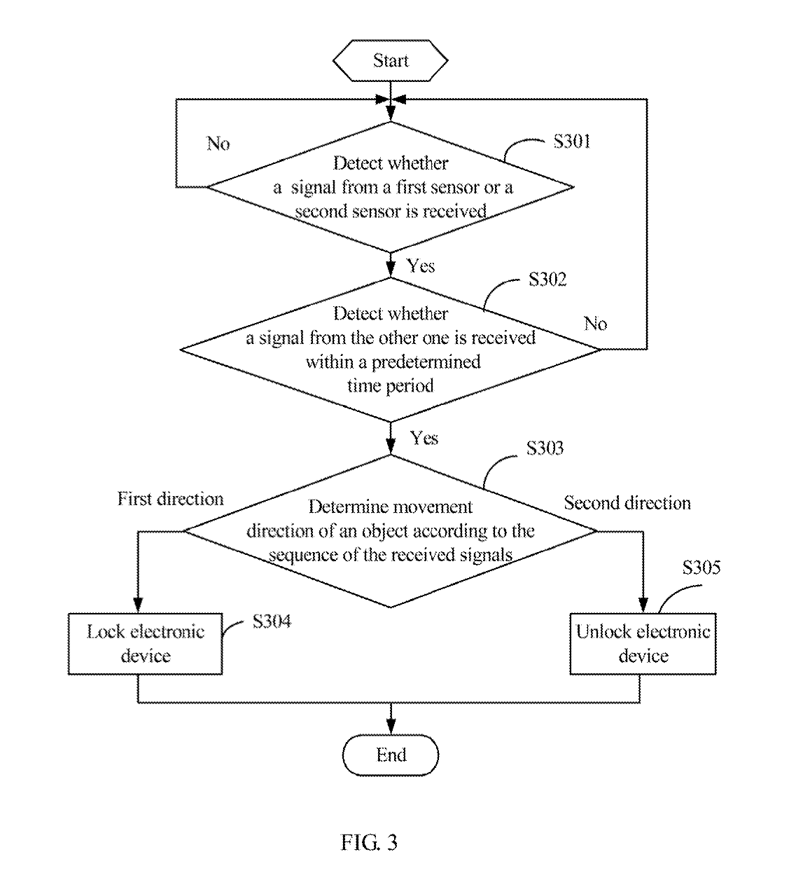

FIG. 3 is a flowchart illustrating a method for selectively locking or unlocking the electronic device 1. In step S301, the processing unit 30 detects whether a signal is from the first sensor 10 or the second sensor 20. In this embodiment, when the first sensor 10 or the second sensor 20 detects an object is within its detection zone, the first sensor 10 or the second sensor 20 generates the signal.

If the processing unit 30 does not receive a signal from either the first sensor 10 or the second sensor 20, the process returns to step S301. Otherwise, in step S302, the processing unit 30 detects whether a signal is received from the other sensor, within a predetermined time period.

If the processing unit 30 does not receive the signal from the other sensor within the predetermined time period, the process returns to step S301. Otherwise, in step S303, the processing unit 30 determines the movement direction of the object according to the sequence of the received signals.

In step S304, the processing unit 30 locks the electronic device 1 if the movement direction of the object is a first direction.

In step S305, the processing unit 30 unlocks the electronic device 1 if the movement direction of the object is a second direction.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a first sensor configured to generate a signal if an object is within its detection zone;
a second sensor configured to generate a signal if the object is within its detection zone; and
a processing unit configured to receive the signals generated by the first sensor and the second sensor, and determine whether to lock or unlock the electronic device according to a sequence of the signals it receives from the first sensor and the second sensor within a predetermined time period.

2. The electronic device according to claim 1, wherein the processing unit is configured to detect whether the signal from the other one of the first sensor and the second sensor is received within the predetermined time period after the processing unit receives the signal from the first sensor or the second sensor, and the processing unit is further configured to determine the movement direction of the object according to the sequence of the signals it receives from the first sensor and the second sensor, and configured to determine whether to lock or unlock the electronic device according to the movement direction of the object.

3. The electronic device according to claim 2, wherein the processing unit locks the electronic device if the movement direction of the object is a first direction, and unlocks the electronic device if the movement direction of the object is a second direction.

4. The electronic device according to claim 3, wherein the first direction is from the first sensor to the second sensor, and the second direction is from the second sensor to the first sensor.

5. The electronic device according to claim 3, wherein the first direction is from the second sensor to the first sensor, and the second direction is from the first sensor to the second sensor.

6. The electronic device according to claim 1, wherein the first sensor and the second sensor are selected from the group consisting of light sensor, infrared sensor, and ultrasonic wave sensor.

7. A method for locking and unlock an electronic device, the electronic device comprising a first sensor and a second sensor, the method comprising:
detecting whether a signal from one of the first sensor and the second sensor is received, the first sensor and the second sensor being configured to generate signals if an object is within its detect zone;
detecting whether a signal from the other one of the first sensor and the second sensor is received within a predetermined time period after receiving the signal from the one of the first sensor and the second sensor; and
determining whether to lock or unlock the electronic device according to a sequence of the signals received from the first sensor and the second sensor.

8. The method according to claim 7, wherein the step of “determining whether to lock or unlock the electronic device according to a sequence of the signals it receives from the first sensor and the second sensor” comprising:
determining movement of the object according to the sequence of the signals it receives from the first sensor and the second sensor;
determining whether to lock or unlock the electronic device according to the movement direction of the object.

9. The method according to claim 8, wherein the step of “determining whether to lock or unlock the electronic device according to the movement direction of the object comprising:
locking the electronic device if the movement direction of the object is a first direction; and
unlocking the electronic device if the movement direction of the object is a second direction.

10. The method according to claim 9, wherein the first direction is from the first sensor to the second sensor, and the second direction is from the second sensor to the first sensor.

11. The method according to claim 9, wherein the first direction is from the second sensor to the first sensor, and the second direction is from the first second sensor to the second sensor.
